(19) United States
(12) Patent Application Publication
(10) Pub. No.: US 2009/0275169 A1
(43) Pub. Date: Nov. 5, 2009

(54) SEMICONDUCTOR DEVICES AND METHODS OF FORMING THE SAME

(76) Inventors: Hyun-Jun Sim, Hawaseong-si (KR); Sok-Hun Choi, Suwon-si (KR); In-Gyu Baek, Seoul (KR); Jin-Shi Zhao, Seoul (KR); Eun-Kyung Yim, Seoul (KR)

Correspondence Address: F. CHAU & ASSOCIATES, LLC, 130 WOODBURY ROAD, WOODBURY, NY, 11797, US

(21) Appl. No.: 12/418,800

(22) Filed: Apr. 6, 2009

(30) Foreign Application Priority Data
Apr. 7, 2008 (KR) 10-2008-0032281

(51) Int. Cl. H01L 21/28

(52) U.S. Cl. 438/104; 257/E21.158

(57) ABSTRACT

A semiconductor device which includes a reaction prevention layer between a resistive memory element and an insulating layer and a method of forming the same.

### CROSS-REFERENCE TO RELATED APPLICATION

This application claims priority under 35 U.S.C. § 119 to Korean Patent Application No. 2008-0032281, filed on Apr. 7, 2008, the entire contents of which are hereby incorporated by reference.

### BACKGROUND OF THE INVENTION

1. Technical Field

The present disclosure relates to a semiconductor device and methods of forming the same, and more particularly to a memory device having a reaction prevention layer and methods of forming the same.

2. Discussion of Related Art

A semiconductor memory device includes a volatile memory device and a nonvolatile memory device. The volatile memory device such as a Dynamic RAM (DRAM) or Static RAM (SRAM) may lose stored data when not powered. The nonvolatile memory device such as a flash memory can maintain stored data even when not powered.

In a semiconductor device such as the flash memory, data can be distinguished by a difference of a resistance generated from a resistive memory element. However, in a conventional art, since a resistive memory element directly contacts an insulating layer including silicon formed thereunder, the material constituting the resistive memory element reacts with the silicon of the insulating layer during a thermal reaction. As a result, a metal silicide layer is formed on a lower part of the resistive memory element. Thus, in the conventional art, the resistive memory element cannot obtain a resistance margin representing different data due to the metal silicide layer formed between the resistive memory element and the insulating layer.

### SUMMARY OF THE INVENTION

Exemplary embodiments provide a semiconductor device. The semiconductor device may include an insulating layer and a reaction prevention layer sequentially stacked on a substrate, a lower electrode having a side surface which is surrounded by the insulating layer and the reaction prevention layer in the insulating layer and the reaction prevention layer, a resistive memory element on the lower electrode and the reaction prevention layer, the resistive memory element including metal oxide and having a bottom surface wider than a top surface of the lower electrode, and an upper electrode on the resistive memory element. The reaction prevention layer may prevent the resistive memory element from reacting to silicon.

Exemplary embodiments provide a method of forming a semiconductor device. The method may include forming a lower electrode in an insulating layer and a reaction prevention layer sequentially stacked on a substrate, forming a resistive memory element on the lower electrode and the reaction prevention layer, and forming an upper electrode on the resistive memory element. The reaction prevention layer may prevent the resistive memory element from reacting to silicon.

### BRIEF DESCRIPTION OF THE DRAWINGS

Exemplary embodiments of the present disclosure can be understood in more detail from the following description taken in conjunction with the accompanying drawings of which:

FIG. 1 is a cross-sectional view of a semiconductor device according to an exemplary embodiment of the present invention;

FIGS. 2 through 5 are cross-sectional views illustrating a method of forming a semiconductor device according to an exemplary embodiment of the present invention;

FIGS. 6 through 9 are cross sectional views illustrating a method of forming a semiconductor device according to an exemplary embodiment of the present invention;

FIGS. 10 through 13 are cross sectional views illustrating a method of forming a semiconductor device according to an exemplary embodiment of the present invention;

FIG. 14 is a cross sectional view of a semiconductor device according to an exemplary embodiment of the present invention;

FIGS. 15 through 17 are cross sectional views illustrating a method of forming a semiconductor device according to an exemplary embodiment of the present invention;

FIG. 18 is a graph showing resistance relative to a thickness of a reaction prevention layer according to an exemplary embodiment of the present invention;

FIG. 19 is a block diagram showing an electronic device including a semiconductor device according to an exemplary embodiment of the present invention; and

FIG. 20 is a block diagram showing a memory system including a semiconductor device according to an exemplary embodiment of the present invention.

### DESCRIPTION OF EXEMPLARY EMBODIMENTS

The present invention will be described more fully hereinafter with reference to the accompanying drawings, in which exemplary embodiments of the present invention are shown. This invention may, however, be embodied in many different forms and should not be construed as limited to the exemplary embodiments set forth herein.

It will be understood that when an element is referred to as being “connected” or “coupled” to another element, it can be directly connected or coupled to the other element or intervening elements may be present.

It will also be understood that when an element such as a layer, region or substrate is referred to as being “on” or “onto” another element, it may lie directly on the other element or intervening elements or layers may also be present.

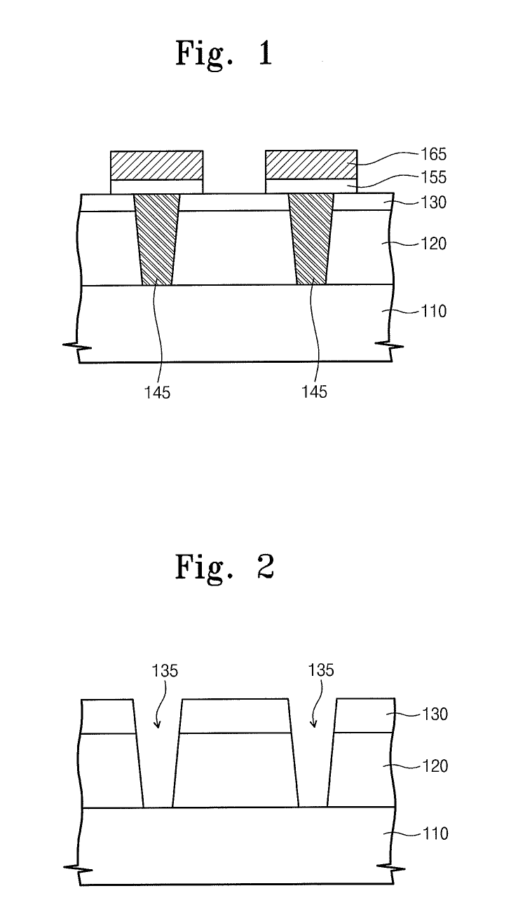

Referring to FIG. 1, a substrate 110 is provided. The substrate 110 can be a semiconductor substrate such as a silicon substrate or a silicon on insulator (SOI) substrate. The substrate 110 may include an active region defined by a device isolation layer. A switching device may be disposed on the active region. An impurity region may be formed in the active region adjacent to the switching device.

An insulating layer 120 and a reaction prevention layer 130 may be disposed on the substrate 110. The insulating layer 120 may include a low dielectric constant material such as, for example, a silicon nitride or a silicon oxide. The reaction prevention layer 130 may include at least one of aluminum oxide (Al₂O₃), hafnium oxide (HfO₂), zirconium oxide (ZrO₂), titanium oxide (TiO₂), magnesium oxide (MgO), niobium oxide (Nb₂O₅), tungsten oxide (W₂O₅), or lanthanide oxide. The lanthanide oxide may include lanthan oxide (La₂O₅), cerium oxide (Ce₂O₅), praseodymium oxide (Pr₂O₅), gadolinium oxide (Gd₂O₅), dysprosium oxide (Dy₂O₅), erbium oxide (Er₂O₅) or yitterbium oxide (Yb₂O₅). The reaction prevention layer 130 may further include doped nitrogen (N). A density of the reaction prevention layer 130 may be increased by doping the reaction prevention layer 130 with the nitrogen (N).

A lower electrode 145 is disposed in the reaction prevention layer 130 and the insulating layer 120. The lower electrode 145 may have a side surface which contacts the reaction prevention layer 130 and the insulating layer 120. The lower electrode 145 may have a bottom surface which contacts an impurity region of the substrate 110. A top surface of the lower electrode 145 is even with a top surface of the reaction prevention layer 130. A diffusion barrier layer may be disposed on the side surface of the lower electrode 145. The diffusion barrier layer may prevent material constituting the lower electrode 145 from being diffused into the outside or may prevent external impurities from being diffused into the lower electrode 145. The lower electrode 145 may include conductive polysilicon, metal or silicide. The metal may include tungsten, copper, iridium, platinum, or ruthenium.

A resistive memory element 155 and an upper electrode 165 are disposed on the reaction prevention layer 130 and the lower electrode 145. A bottom surface of the resistive memory element 155 may contact a top surface of the lower electrode 145. The bottom surface of the resistive memory element 155 may be larger than the top surface of the lower electrode 145. For instance, the resistive memory element 155 may cover the entire top surface of the lower electrode 145 and may extend onto the reaction prevention layer 130 near the lower electrode 145.

The resistive memory element 155 may include transition metal. The resistive memory element 155 may include material that is available for silicidation. The resistive memory element 155 may include, for example, tantalum oxide, titanium oxide, molybdenum oxide, tungsten oxide, cobalt oxide, palladium oxide or platinum oxide. The resistive memory element 155 may include at least one of nickel oxide, vanadium oxide, (Pr, Ca)MnO₃ (PCMO), strontium-titanium oxide, barium-strontium-titanium oxide, strontium-zirconium oxide, barium-zirconium oxide or barium-strontium-zirconium oxide. The upper electrode 165 may include the same material as the lower electrode 145. In an exemplary embodiment, at least one of the upper and lower electrodes 165 and 145 may include metal.

A capping layer may be conformally disposed on the resistive memory element 155 and the upper electrode 165. The capping layer may include the same material as the reaction prevention layer 130. A contact may be disposed on the upper electrode 165. The contact is electrically connected to the upper electrode 165. A bit line which is electrically connected to the contact may be disposed thereon. A number of metal interconnections may be disposed thereon.

Referring to FIGS. 2 through 5, a method of forming a semiconductor device according to an exemplary embodiment of the present invention is shown.

Referring to FIG. 2, the insulating layer 120 is disposed on the substrate 110.

The reaction prevention layer 130 is formed on the insulating layer 120. The reaction prevention layer 130 may be formed by, for example, a physical vapor deposition (PVD) process, a chemical vapor deposition (CVD) process or an atomic layer deposition (ALD) process.

A patterning process may be applied to the reaction prevention layer 130 and the insulating layer 120 to define a lower electrode region 135. The patterning process may be performed to expose a portion of a top surface of the substrate 110. The portion of the top surface can be an impurity region. A top surface of the substrate 110 is exposed to form a bottom surface of the lower electrode region 135. The reaction prevention layer 130 and the insulating layer 120 is exposed to form a side surface of the lower electrode region 135.

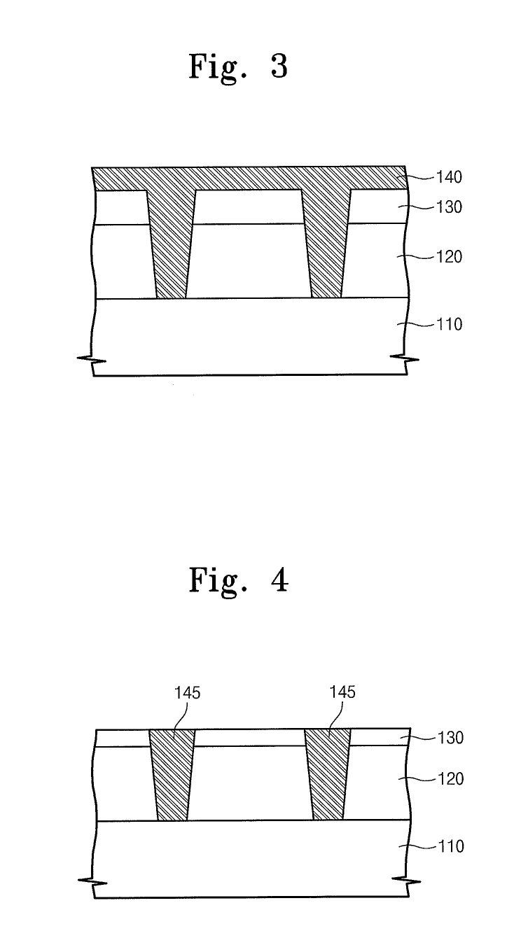

Referring to FIG. 3, a conductive layer 140 is formed in the lower electrode region 135 and the reaction prevention layer 130. The conductive layer 140 may include conductive polysilicon, metal or silicide. The metal may include tungsten, copper, iridium, platinum or ruthenium.

Referring to FIG. 4, the conductive layer 140 is planarized to expose a top surface of the reaction prevention layer 130. The planarization may be performed by, for example, a chemical mechanical polishing (CMP) process. The lower electrode 145 filling the lower electrode region 135 is formed by, for example, the planarization process. The lower electrode 145 may have a side surface which contacts the reaction prevention layer 130 and the insulating layer 120. The diffusion barrier layer is disposed on the side surface of the lower electrode 145.

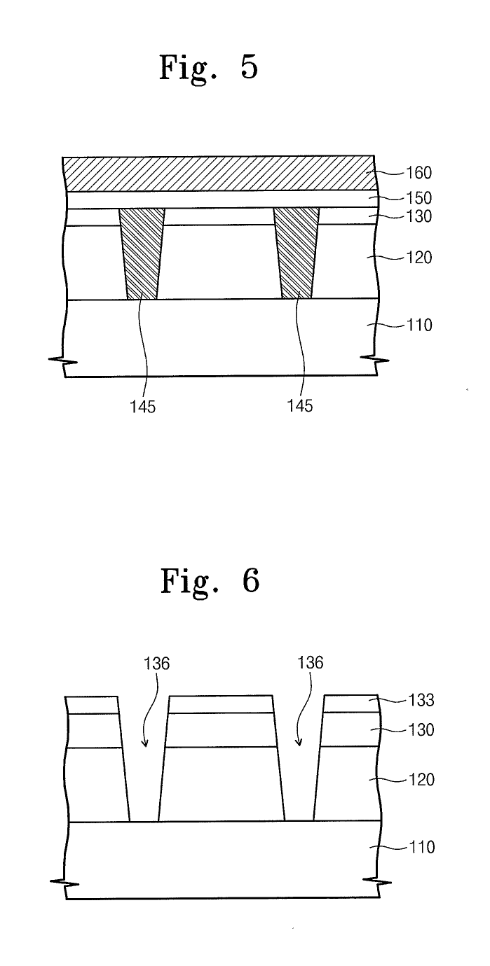

Referring to FIG. 5, a metal oxide layer 150 is formed on the reaction prevention layer 130 and the lower electrode 145. The metal oxide layer 150 may include transition metal. The metal oxide layer 150 may include material that is available for silicidation. The metal oxide layer 150 may include tantalum oxide, titanium oxide, molybdenum oxide, tungsten oxide, cobalt oxide, palladium oxide or platinum oxide. The oxide metal layer 150 may include at least one of nickel oxide, vanadium oxide, PCMO ((Pr, Ca)MnO₃), strontium-titanium oxide, barium-strontium-titanium oxide, strontium-zirconium oxide, barium-zirconium oxide and barium-strontium-zirconium oxide.

An upper electrode conductive layer 160 is formed on the metal oxide layer 150. A material constituting the upper electrode conductive layer 160 is the same as that of the upper electrode 165.

A patterning process may be performed to sequentially etch the upper electrode conductive layer 160 and the metal oxide layer 150. Referring to FIG. 1, the resistive memory element 155 and an upper electrode 165 are formed on the reaction prevention layer 130 and the lower electrode 145 by the patterning process.

The capping layer may be conformally disposed on the resistive memory element 155 and the upper electrode 165. The capping layer may include the same material as the reaction prevention layer 130. An insulating interlayer may be formed thereon. A contact electrically connected to the upper electrode 165 through the insulating interlayer may be formed. A bit line electrically connected to the contact may be formed on the insulating interlayer. The process described above may be repeatedly performed to form a number of insulating layers and metal interconnections. Without the reaction prevention layer 130, a silicide layer may be generated by a reaction of the resistive memory element 155 and the silicon from the insulating layer 120 in a temperature of more than about 400° C. For instance, the resistive memory element 155 including metal may react with silicon on the insulating layer 120, thereby generating the silicide layer. In an exemplary embodiment, the resistive memory element 155 and the insulating layer 120 is isolated from each other by the reaction prevention layer 130.

Referring to FIGS. 6 through 9, a method of forming a semiconductor device according to an exemplary embodiment of the present invention is described.

Referring to FIG. 6, a sacrifice layer 133 may be formed on the reaction prevention layer 130. The sacrifice layer 133 may include an insulating material. The sacrifice layer 133 may include a silicon oxide or a silicon nitride and may be formed by a high density plasma deposition process.

The sacrifice layer 133, the reaction prevention layer 130 and the insulating layer 120 may be patterned to define a lower electrode region 136. A top surface of the substrate 110 is exposed to form a bottom surface of the lower electrode region 136. The sacrifice layer 133, the reaction prevention layer 130 and the insulating layer 120 may be exposed to form a side surface of the lower electrode region 136.

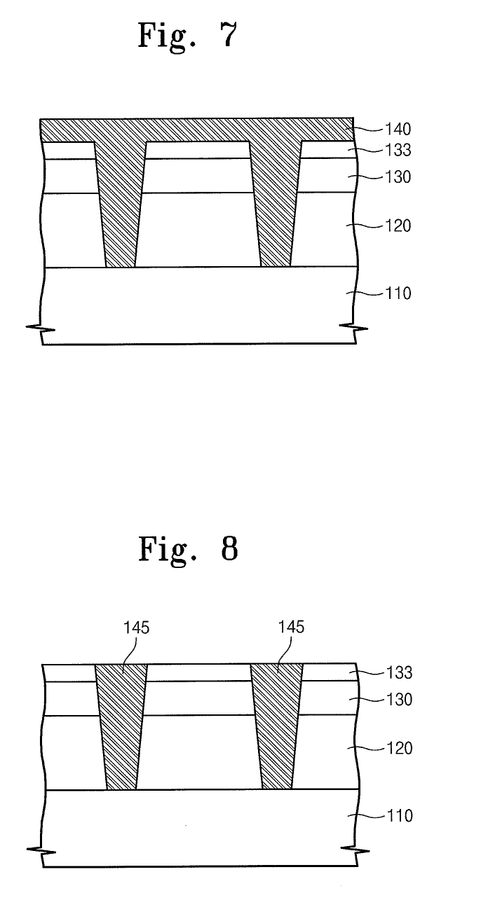

Referring to FIG. 7, the conductive layer 140 is formed in the lower electrode region 136 and on the sacrifice layer 133.

Referring to FIG. 8, the conductive layer 140 is planarized down to the top surface of the sacrifice layer 133. The planarization process may be performed by a chemical mechanical polishing (CMP) process. A substantial portion of the conductive layer 140 may be removed during the planarization process. Without the sacrifice layer 133, a portion of the reaction prevention layer 130 can also be removed during the planarization process when an etching control of the conductive layer 140 and the reaction prevention layer is difficult. For example, the conductive layer 140 comprises tungsten and the reaction prevention layer comprises aluminum oxide. Thus, in an exemplary embodiment, the sacrifice layer 133 protects the reaction prevention layer 130 during the planarization process. The lower electrode 145 filling the lower electrode region 136 may be formed by the planarization process. A side surface of the lower electrode 145 contacts the sacrifice layer 133, the reaction prevention layer 130 and the insulating layer 120. In an exemplary embodiment, a barrier layer may be formed on the side surface of the lower electrode 145.

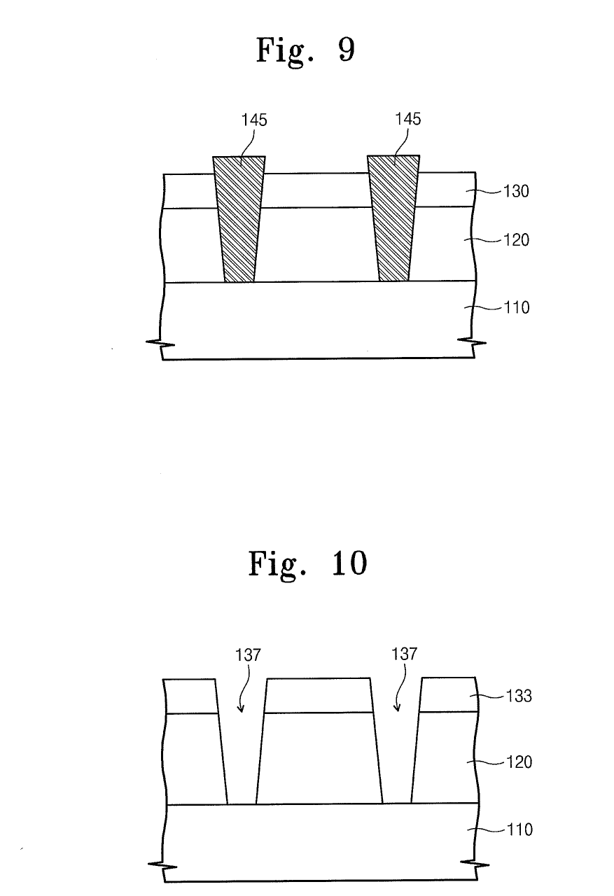

Referring to FIG. 9, the sacrifice layer 133 is removed. The sacrifice layer 133 may be removed by, for example, an etch-back process. The lower electrode 145 which contacts the sacrifice layer 133 may be simultaneously removed during a removal of the sacrifice layer 133. A protruded portion of the lower electrode 145 may be removed by a planarization process such as, for example, the chemical mechanical polishing process (CMP).

The resistive memory element 155 and an upper electrode 165 are formed on the reaction prevention layer 130 and the lower electrode 145.

Referring to FIGS. 10 through 13, a method of forming a semiconductor device according to an exemplary embodiment of the present invention is described.

Referring to FIG. 10, the insulating layer 120 including a silicon nitride is formed on the substrate 110. The sacrifice layer 133 is formed on the insulating layer 120.

The sacrifice layer 133 and the insulating layer 120 may be patterned to define a lower electrode region 137. A top surface of the substrate 110 may be exposed to form a bottom surface of the lower electrode region 137. The sacrifice layer 133 and the insulating layer 120 may be exposed to form a side surface of the lower electrode region 137.

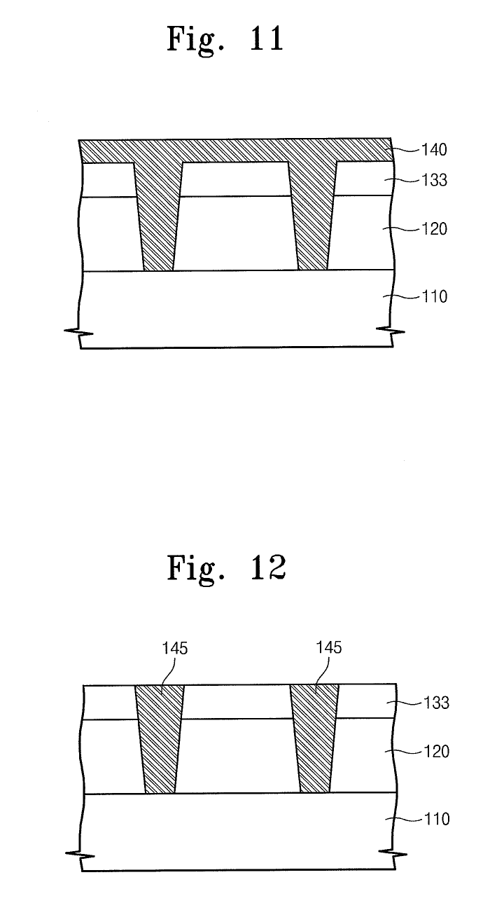

Referring to FIG. 11, the conductive layer 140 may be formed in the lower electrode region 137 and on the sacrifice layer 133.

Referring to FIG. 12, the conductive layer 140 may be planarized to expose a top surface of the sacrifice layer 133. The planarization process may be performed by the chemical mechanical polishing (CMP) process. During the planarization process, a substantial portion of the conductive layer 140 is removed. The lower electrode 145 filling the lower electrode region 137 may be formed by the planarization process. The lower electrode 145 has a side surface which contacts the sacrifice layer 133 and the insulating layer 120. In an exemplary embodiment, a barrier layer may be formed on the side surface of the lower electrode 145.

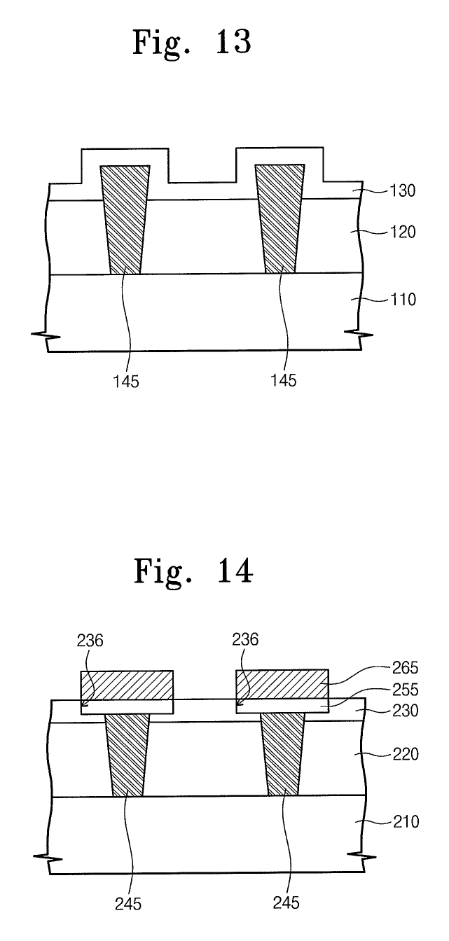

Referring to FIG. 13, the sacrifice layer 133 is selectively removed. The sacrifice layer 133 may be removed by, for example, an etch-back process. The lower electrode 145 may be exposed by, for example, an etch-back process. The reaction prevention layer 130 is formed on the exposed lower electrode 145 and the insulating layer 120. The reaction prevention layer 130 may be formed by, for example, a physical vapor deposition (PVD) method, a chemical vapor deposition (CVD) method and/or an atomic layer deposition (ALD) method.

Referring to FIGS. 1 and 13, a planarization process may be applied to the reaction prevention layer 130. A top surface of the lower electrode 145 may be even with a top surface of the reaction prevention layer 130 by the planarization process.

The resistive memory element 155 and the upper electrode 165 may be formed on the reaction prevention layer 130 and the lower electrode 145.

Referring to FIG. 14, a semiconductor device according to an exemplary embodiment of the present invention is described.

A substrate 210 including an active region is provided. A switching device may be disposed in the active region. An impurity region may be defined in an active region adjacent to the switching device.

An insulating layer 220 and a reaction prevention layer 230 may be stacked on the substrate 210. The insulating layer 220 may include silicon nitride. The reaction prevention layer 230 may include at least one of aluminum oxide (Al₂O₃), hafnium oxide (HfO₂), zirconium oxide (ZrO₂), titanium oxide (TiO₂), magnesium oxide (MgO), niobium oxide (Nb₂O₅), tungsten oxide (W₂O₅), and lanthanide oxide. The lanthanide oxide may include lanthan oxide (La₂O₅), cerium oxide (Ce₂O₅), praseodymium oxide (Pr₂O₅), gadolinium oxide (Gd₂O₅), dysprosium oxide (Dy₂O₅), erbium oxide (Er₂O₅) and yitterbium oxide (Yb₂O₅). The reaction prevention layer 230 may further include doped nitrogen (N). A density of the reaction prevention layer 230 may be increased by doping the reaction prevention layer 230 with nitrogen.

The reaction prevention layer 230 may include a trench 236. A lower electrode 245 may be disposed in the trench 236 of the reaction prevention layer 230 and the insulating layer 220. A bottom surface of the trench 236 may expose a top surface of the lower electrode 245 and a portion of region of the reaction prevention layer 230 adjacent to the top surface of the lower electrode 245. A side surface of the trench 236 may expose the reaction prevention layer 230.

The lower electrode 245 may have a side surface which contacts the reaction prevention layer 230 and the insulating layer 220. The lower electrode 245 may have a bottom surface which contacts an impurity region of the substrate 210. In an exemplary embodiment, a diffusion barrier layer may be disposed on the side surface of the lower electrode 245. The lower electrode 245 may include conductive polysilicon, metal or silicide. For instance, the metal may include tungsten, copper, iridium, platinum or ruthenium.

A resistive memory element 255 may be disposed in the trench 236. A top surface of the resistive memory element 255 may be even with a top surface of the reaction prevention layer 230. A side surface of the resistive memory element 255 may contact the reaction prevention layer 230. A bottom surface of the resistive memory element 255 may contact the lower electrode 245 and the reaction prevention layer 230. A bottom surface of the resistive memory element 255 may be wider than a top surface of the lower electrode 245. The resistive memory element 255 may include the same material as the resistive memory element 155.

An upper electrode 265 may be disposed on the resistive memory element 255. The upper electrode 265 may be disposed to cover an entire top surface of the resistive memory element 255. The upper electrode 265 may include the same material as the lower electrode 245. At least one of the upper electrode 265 and the lower electrode 245 may include, for example, metal.

A contact electrically connected to the upper electrode 265 may be disposed on the upper electrode 265. A bit line electrically connected to the contact may be disposed thereon. A number of metal interconnections may be disposed thereon.

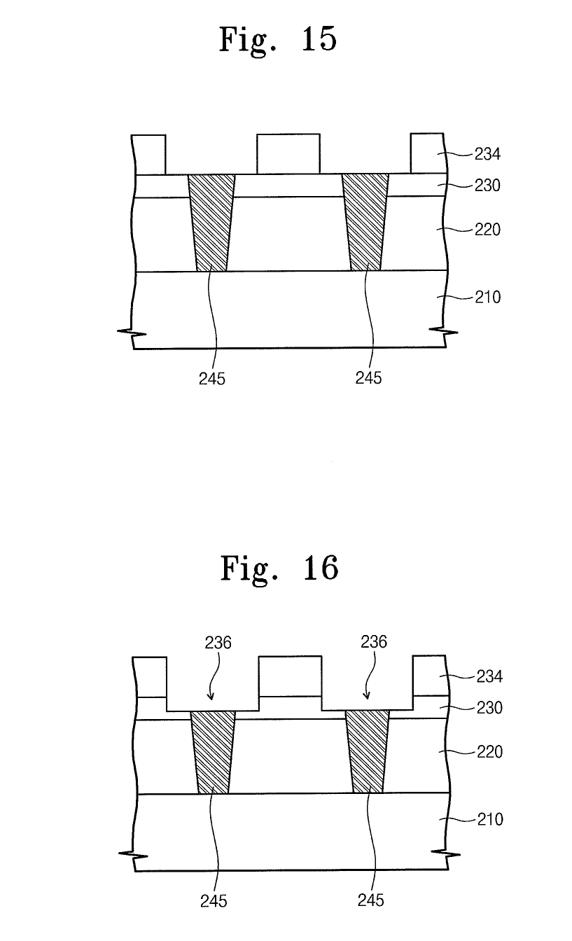

Referring to FIGS. 15 through 17, a method of forming a semiconductor device according to an exemplary embodiment of the present invention is described.

Referring to FIG. 15, the insulating layer 220 including, for example, a silicon nitride is formed on the substrate 210.

The reaction prevention layer 230 may be formed on the insulating layer 220. The reaction prevention layer 230 may be formed by a physical vapor deposition (PVD) method, a chemical vapor deposition (CVD) method and/or an atomic layer deposition (ALD) method. The reaction prevention layer 230 may include at least one of aluminum oxide (Al₂O₃), hafnium oxide (HfO₂), zirconium oxide (ZrO₂), titanium oxide (TiO₂), magnesium oxide (MgO), niobium oxide (Nb₂O₅), tungsten oxide (W₂O₅), or lanthanide oxide. The lanthanide oxide may include lanthan oxide (La₂O₅), cerium oxide (Ce₂O₅), praseodymium oxide (Pr₂O₅), gadolinium oxide (Gd₂O₅), dysprosium oxide (Dy₂O₅), erbium oxide (Er₂O₅) and yitterbium oxide (Yb₂O₅). The reaction prevention layer 230 may further include doped nitrogen (N). A density of the reaction prevention layer 230 may be increased by doping the reaction prevention layer 230 with nitrogen.

In an exemplary embodiment, a lower electrode 245 is formed in the insulating layer 220 and the reaction prevention layer 230 by, for example, a patterning process, a filling process and a planarization process. The lower electrode 245 may have a side surface which contacts the insulating layer 220 and the reaction prevention layer 230. The lower electrode 245 may include conductive polysilicon, metal or silicide. The lower electrode 245 may include conductive polysilicon, metal or silicide. For instance, the metal may include tungsten, copper, iridium, platinum or ruthenium. In an exemplary embodiment, a diffusion barrier layer is disposed on the side surface of the lower electrode 245.

A mask pattern 234 may be formed on the reaction prevention layer 230. The mask pattern 234 may include an insulating material. For example, the mask pattern 234 may include a material having an etching selectivity with respect to the reaction prevention layer 230 and the lower electrode 245. An entire top surface of the lower electrode 245 and a portion of a top surface of the reaction prevention layer 230 adjacent to the lower electrode 245 may be exposed by the mask pattern 234.

Referring to FIG. 16, exposed regions of the lower electrode 245 and the reaction prevention layer 230 may be etched using the mask pattern 234 as an etching mask. A recess region 236 may be formed by the etching process. The lower electrode 245 and the reaction prevention layer 230 may be exposed to form a bottom surface of the recess region 236. The reaction prevention region 230 may be exposed to form a side surface of the recess region 236.

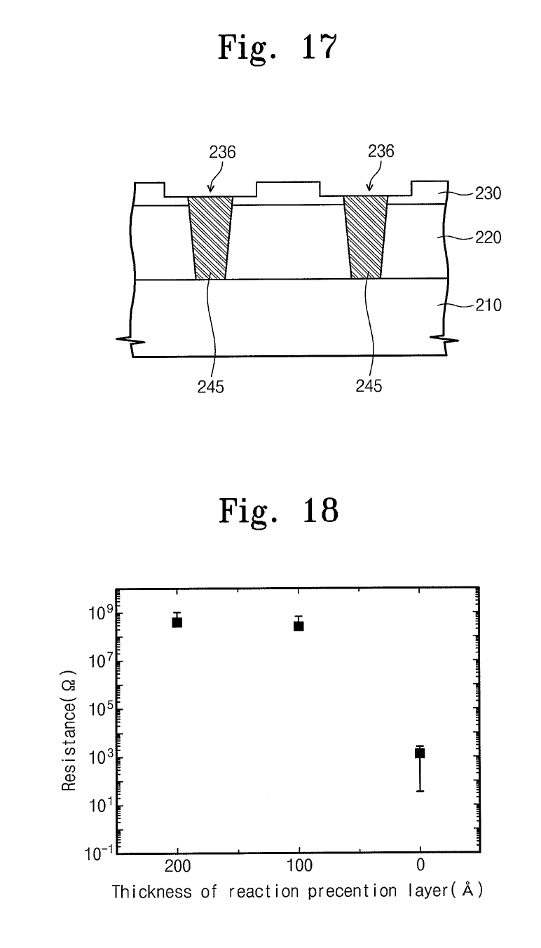

Referring to FIG. 17, the mask pattern 234 is removed.

Referring to FIG. 14, the resistive memory element 255 is formed in the recess region 236 and the upper electrode 265 is formed on the resistive memory element 255.

In an exemplary embodiment, a metal oxide layer is formed on the recess region 236 and the reaction prevention layer 230, and the metal oxide layer is planarized to form the resistive memory element 255. A conductive layer is formed on the resistive memory element 255 and the reaction prevention layer 230, and the conductive layer is patterned to cover an entire top surface of the resistive memory element 255. As a result, the upper electrode 265 may be formed.

The upper electrode 265 may include the same material as the lower electrode 145. At least one of the upper electrode 265 and the lower electrode 145 may include, for example, metal.

A contact electrically connected to the upper electrode 265 and a bit line electrically connected to the contact may be formed. Metal interconnections may also be formed. A silicide layer may be formed at more than about 400° C. during the interconnection process by the reaction between the silicon and metal. The resistive memory element 255 including metal reacts with the silicon of the insulating layer 220 to form a silicide layer. In an exemplary embodiment, the reaction prevention layer 230 may prevent the resistive memory element 255 from reacting with the silicon of the insulating layer 220.

FIG. 18 is a graph showing resistance relative to a thickness of a reaction prevention layer. Referring to FIG. 18, a semiconductor device including a reaction prevention layer having a thickness of about 100 Å or about 200 Å between an insulating layer and a resistive memory element is provided according to an exemplary embodiment of the present invention. In a comparative example, the reaction prevention layer is not provided such that the thickness of the reaction prevention layer is zero (0).

A semiconductor device according to an exemplary embodiment of the present invention represents data “0” and data “1” according to a resistive value of the resistive memory element. A resistance of a resistive memory element representing data “0” is high and a resistance of a resistive memory element representing data “1” is relatively low. A difference of a resistance between data “0” and data “1” may be set to be about 10³ Ω. A resistance of a resistive memory element having data “1” may be set to be about 10⁴ Ω to 10⁵ Ω.

In FIG. 18, a semiconductor device having a resistive memory element having data “0” is provided. A read voltage (Vread) is applied to resistive memory elements of exemplary embodiments and the comparative example. The read voltage may be about 0.8V. Referring to FIG. 18, a resistance of a resistive memory element according to an exemplary embodiment is about 10⁸ Ω to about 10⁹ Ω, and a resistance of the comparative example is about 10³Ω. The resistance of a resistive memory element according to the comparative example is lower than a resistance of data “1”. That is, a semiconductor device without the reaction prevention layer cannot represent a required data.

In an exemplary embodiment, the resistive memory elements can maintain the resistive characteristics because a reaction prevention layer prevents a resistive memory element from reacting with silicon.

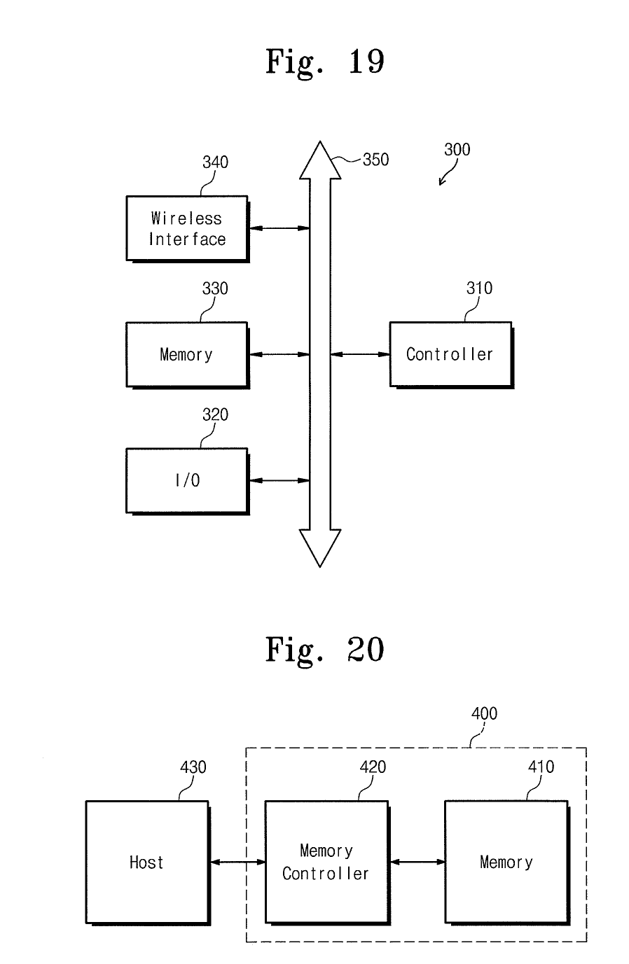

Referring to FIG. 19, an electronic device 300 including a semiconductor device according to an exemplary embodiment of the present invention is described. The electronic device 300 may be used in a wireless communication device such as, for example, a PDA, a laptop computer, a mobile computer, a web tablet, a cellular phone, a wireless telephone and a digital music player or devices which can transfer and/or receive data in a wireless environment.

The electronic device 300 may include a controller 310, input/output devices 320, a memory 330 and a wireless interface 340 which are combined with each other through a bus 350. The input/output devices 320 can be, for example, a key pad, key board or a display. The controller 310 may include, for example, at least one of microprocessor, digital signal process, or microcontroller. The memory 330 may be used for storing an instruction executed by the controller 310. The memory 330 may also be used for storing user data. The memory 330 includes a semiconductor device according to exemplary embodiments of the present invention.

The electronic device 300 may use a wireless interface 340 to transfer data to a wireless communication network communicating with an RF signal or receive data from a network. The wireless interface 340 may include, for example, an antenna or a wireless transceiver.

The electronic device 300 according to exemplary embodiments of the present invention may be used in a communication interface protocol such as third generation communication system, for example, CDMA, GSM, NADC, E-TDMA, WCDMA, and CDMA2000.

Referring to FIG. 20, a memory system including a semiconductor device according to exemplary embodiments of the present invention is described.

A memory system 400 may include a memory device 410 for storing data and a memory controller 420. The memory controller 420 controls the memory device 410 to read data stored in the memory device 410 or write data into the memory device 410 in response to read/write requests of a host 430. The memory controller 420 may constitute an address mapping table for mapping an address provided from the host 430 such as, for example, a mobile device or a computer system into a physical address.

Although exemplary embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

1.-9. (canceled)

10. A method of forming a semiconductor device, comprising:
forming a lower electrode in an insulating layer and a reaction prevention layer disposed on a substrate;
forming a resistive memory element on the lower electrode and the reaction prevention layer; and
forming an upper electrode on the resistive memory element.

11. The method of claim 10, wherein the reaction prevention layer prevents the resistive memory element from reacting with silicon on the insulating layer.

12. The method of claim 10, wherein forming the resistive memory element comprises;
forming a metal oxide layer on the lower electrode and the reaction prevention layer; and
patterning the metal oxide layer so that the resistive memory element is disposed on the lower electrode and the reaction prevention layer.

13. The method of claim 10, wherein forming the lower electrode comprises:
forming the insulating layer on the substrate;
forming the reaction prevention layer on the insulating layer;
patterning the reaction prevention layer and the insulating layer to form a lower electrode region; and
filling the lower electrode region with a conductive material.

14. The method of claim 13, further comprising forming a sacrifice layer defining the lower electrode region on the reaction prevention layer.

15. The method of claim 14, wherein filling the lower electrode region comprises;
forming a conductive layer on the lower electrode region and the sacrifice layer;
planarizing the conductive layer to expose the sacrifice layer;
removing the sacrifice layer; and
planarizing the lower electrode so that a top surface of the lower electrode is even with a top surface of the reaction prevention layer.

16. The method of claim 13, further comprising:
forming a mask pattern exposing the lower electrode and the reaction prevention layer adjacent to the lower electrode; and
recessing the exposed lower electrode and the exposed reaction prevention layer adjacent to the lower electrode using the mask pattern, wherein a side surface of the resistive memory element is surrounded by the reaction prevention layer.

17. The method of claim 10, wherein forming the lower electrode comprises:
forming the insulating layer on the substrate;
forming the sacrifice layer on the insulating layer;
patterning the sacrifice layer and the insulating layer to form a lower electrode region;
forming a conductive layer on the lower electrode region and the sacrifice layer;
planarizing the conductive layer to expose the sacrifice layer;
removing the sacrifice layer;
forming the reaction prevention layer on the insulating layer and the lower electrode; and
planarizing the reaction prevention layer so that a top surface of the reaction prevention layer is even with a top surface of the lower electrode.

18. The method of claim 10, wherein the reaction prevention layer prevents a thermally activated reaction.

19. The method of claim 10, wherein the reaction prevention layer comprises at least one of aluminum oxide, hafnium oxide, zirconium oxide, titanium oxide, magnesium oxide, niobium oxide, tungsten oxide or lanthanide oxide.

20. The method of claim 19, wherein the reaction prevention layer further comprises nitrogen.
